(19) United States
(12) Patent Application Publication
(10) Pub. No.: US 2018/0102491 A1
(43) Pub. Date: Apr. 12, 2018

(54) ORGANIC PHOTODETECTORS AND PRODUCTION METHOD THEREOF

(71) Applicant: TECHNISCHE UNIVERSITÄT DRESDEN, Dresden (DE)

(72) Inventors: Ji-Ling HOU, Dresden (DE); Axel FISCHER, Dresden (DE); Daniel KASEMANN, Dresden (DE); Sheng-Chieh YANG, Dresden (DE); Karl LEO, Dresden (DE)

(73) Assignee: TECHNISCHE UNIVERSITÄT DRESDEN, Dresden (DE)

(21) Appl. No.: 15/578,500

(22) PCT Filed: Jun. 17, 2016
(86) PCT No.: PCT/EP2016/064040

§ 371 Date: Nov. 30, 2017

(30) Foreign Application Priority Data
Jun. 19, 2015 (DE) 10 2015 109 899.7

(51) Int. Cl. H01L 51/42; H01L 51/44

(52) U.S. Cl. CPC H01L 51/4206; H01L 51/447; H01L 51/441; H01L 51/428

(57) ABSTRACT

An organic photodetector for detecting infrared, visible and ultraviolet radiation is provided with a tunable spectral response to achieve a high responsivity at different design wavelengths. The organic photodetector comprises at least a substrate, a first electrode, a second electrode and at least one organic material, which is arranged between the first and the second electrodes, wherein a Schottky barrier is formed at the interface between the first electrode and the organic material and/or at the interface between the second electrode and the organic material. The tunability in the responsivity of the organic photodetector is achieved by structuring at least one electrode so that it comprises nano-apertures for exciting surface plasmon resonances.

### FIELD OF THE INVENTION

The invention relates to organic photodetectors which may be used for detecting infrared, visible, or ultraviolet radiation. More particularly, it is directed to organic photodetectors having a tunable spectral response. The invention further relates to a method for producing the same.

### BACKGROUND OF THE INVENTION

A photodetector is a device which measures photon flux or optical power by converting energy of the absorbed photons into a measurable signal. Typically, photodetectors convert light into an electrical current where the photodetectors are connected to current detecting circuits and may receive a bias voltage in order to detect or sense light with high sensitivity. This is in contrast to photovoltaic devices, which are operated without a bias, and which are specifically used to generate an electrical power from the energy of the absorbed photons. Photodetectors may be used as optical receivers in optical communication systems, sensors in imaging systems, detectors in spectrometry applications, and many more. There are many types of photodetectors, for example photodiodes, metal-semiconductor-metal (MSM) photodetectors, phototransistors, photoresistors, thermal detectors, etc.

One important characteristic of photodetectors is the responsivity, which is defined as the ratio of generated photocurrent to the incident radiant power at a given wavelength. The responsivity is a function of the wavelength of the incident radiation and of the material properties, such as the bandgap of the material of which the photodetector is made. The spectral response of photodetectors is typically limited by the bandgap of the material since only photon energies greater than the bandgap energy can be detected.

Photodetectors are typically fabricated using inorganic semiconductor materials such as silicon, indium gallium arsenide, germanium and/or lead sulfide. Fabrication of such photodetectors is a technically complex and expensive process. In comparison with inorganic photodetectors, organic photodetectors have drawn interest for photodetection due to a multitude of advantages. Organic semiconductors offer the opportunity to produce flexible and (semi)transparent devices as well as large area devices in simple low-temperature and low-cost fabrication processes, such as solution processing, at low material cost. There is a large variety of organic molecules which can be prepared by chemical methods. The active area can be structured with low resolution at low cost. Furthermore, organic electronic devices feature the advantages of being stackable, which offers the possibility to combine them with other, inorganic or organic, devices, e.g. to fabricate an organic device on top of CMOS. Similarly, they can be integrated into transistor structures.

One possible approach to achieve a tunable spectral response is to use multiple and/or tunable wavelength filters located upstream of the detector elements. Another approach is to use a detector array which consists essentially of two or more separate detector arrays stacked on top of each other, with each detector array designed to be sensitive to a different spectral band.

US 2014 0001455 A1 discloses spectrally tunable broadband organic photodetectors using a stacked or tandem architecture in a single photodetector device structure. The photodetector device includes multiple organic photodetector sub-cells arranged in a stack, with each organic photodetector sub-cell being configured to generate an electrical current in response to light absorption over a corresponding range of wavelengths. The response from each individual active material can be separately tuned, thereby achieving wide tunability in the optical responsivity of the organic photodetector.

A disadvantage of the reported device, and a general disadvantage of photodetectors with photoactive semiconducting layers, is that the selection of photoactive materials is restricted since the materials have to provide a suitable bandgap to match the design wavelength of interest. Furthermore, in order to allow incident light to enter photodetectors efficiently, an electrode with high transmittance is generally required, for example indium tin oxide (ITO). The choice of both materials has to further meet the requirements of forming a good Schottky barrier in order to reduce leakage current. Besides, current fabrication processes of photodetectors are very expensive, complex, and difficult to integrate with flexible substrates.

Due to the lack of low-energy-gap organic materials and suitable molecular combinations for efficient exciton dissociation, considerable effort has been put in material synthesis, heterojunction design or quantum-dot incorporation to reach photodetection wavelengths corresponding to the near-infrared to infrared region, which is of particular interest for many applications, such as optical communication, spectroscopy, and biological sensing. However, high non-radiative recombination and the absorption of the C—H, N—H, and O—H covalent bonds are expected to affect the behavior in the NIR spectral region, when the absorption edge is made to extend further, inhibiting the generation of photocurrent.

In order to circumvent this problem and to reach longer photodetection wavelengths, Schottky barrier photodetectors have been proposed, where the detection mechanism is based on internal photoemission across a Schottky barrier between a metal and a semiconductor or dielectric.

It is known that the efficiency of photoemission can be significantly enhanced by sub-wavelength structures on metal electrodes due to the excitation of surface plasmon resonances at the metal/semiconductor interface. WO 2015/081327 discloses LEDs where the top metallic layer is light transmissive and has lateral sub-wavelength structures in order to enhance emission efficiency, contrast and brightness. A photoactive, light emitting semiconducting material is provided between the top and bottom metallic layer, which features the above-mentioned disadvantage of a restricted choice of suitable materials. A photovoltaic device with nano-cavities on a thin, photoactive organic semiconducting layer is disclosed in US 2010/0206380.

Plasmonic enhancement of the performance of photodetectors with photoactive inorganic semiconductors has been reported in US 2006/0175551 A1 and US 2012/0205541 A1. US 2014/0319357 A1 discloses the use of graphene as the photoactive layer in a photodetector with periodically arranged, isolated metal structures on the graphene layer. Disadvantageously, the fabrication of sufficiently large graphene monolayers is difficult.

In order to avoid the restrictions described above concerning the selection of photoactive material, plasmonic Schottky photodetectors have been proposed for inorganic materials. US 2008/0266640 A1 discloses a modulator with nano-apertures at an interface with an inorganic semiconductor configured to select a predetermined subwavelength of light. Wang and Melosh describe surface plasmon excitation within a metal-inorganic insulator-metal device (F. Wang and N. A. Melosh, Nano Lett. 11 (2011) 5426). Plasmons excited in the upper metal are absorbed, creating a high concentration of hot electrons which can be injected above or tunnel through the thin insulating barrier, producing current. A photodetector with a planar metal-oxide-metal structure is disclosed by Chalabi et al. (H. Chalabi, D. Schoen, and M. L. Brongersma, Nano Lett. 14 (2014) 1374), wherein one of the metallic contacts has been reshaped into a plasmonic stripe antenna. Disadvantageously, due to the fact that there is only a very limited amount of inorganic materials with appropriate semiconducting or dielectric properties available, the flexibility in tuning the bandstructure of the inorganic material and thus in tuning the height of the Schottky barrier is low, which limits the tunability of the responsivity in inorganic plasmonic Schottky detectors. Apart from this, compared with organic devices, these inorganic photodetectors feature the well-known disadvantages of mechanical rigidness and complex and cost-intensive processing, among others.

In this regard, using organic materials in Schottky photodetectors has the advantage that the flexibility in generating different bandstructures per “molecular engineering” is very high, which gives the opportunity to adjust the height of the Schottky barrier.

Still, there are many fundamental differences in the physical properties of inorganic and organic semiconductors that prevent a direct transfer of the concepts used for inorganic devices to organic devices. One of them is that, due to the weaker intermolecular bonding in amorphous or polycrystalline organic semiconductors, the delocalization of electronic wave functions is much weaker in organic semiconductors compared to single-crystalline inorganic semiconductors. Charge transport in organic semiconductors is therefore dominated by hopping, which results in a significantly lower charge carrier mobility.

In Sci Rep. 6 (2016), 19794, van der Kaap and Koster show that, for injected hot electrons in a typical organic semiconductor, rapid energetic relaxation occurs, which is much faster than the typical transit time of a charge carrier through a device. They conclude that the impact of energetically hot carriers on device operation is limited. This implies that the concept of hot carrier injection cannot be advantageously applied to organic photodetectors.

### GENERAL DESCRIPTION OF THE INVENTION

An object of the present invention is to provide an organic photodetector with a tunable spectral response, in particular for optical detecting at visible and infrared wavelengths, which is compatible with low-cost organic semiconductor fabrication and can overcome the problems of the prior art. Another object of the invention is to provide a production method thereof.

The object of the invention is achieved by the subject matter of the independent claims. Advantageous embodiments of the invention are specified in the dependent claims.

According to the invention, a new type of organic photodetector for detecting infrared, visible and ultraviolet radiation is provided with a tunable spectral response to achieve high responsivity at different and selectable design wavelengths, i. e. target wavelengths. The design wavelength of the organic photodetector according to the invention corresponds to the wavelength in the desired wavelength range (e.g. in the infrared) where the responsivity has a maximum.

The organic photodetector comprises a substrate, and on the substrate a layer stack comprising at least a first electrode, a second electrode and at least one organic material which is arranged between the first and the second electrode. At least one of the electrodes has a surface exposed to incident radiation. That means that e.g. the first electrode has such a position within the layer stack that it is faced to the incident radiation. In general, both electrodes can be transparent and photoactive. The term “photoactive electrode” means here that such an electrode has an enhanced absorption of light/photon in comparison to the absorption which is always caused by the material, e.g. due to a structuring of the electrode as described below. The organic material layer, which is arranged between the first and the second electrode, is preferably made of organic oligomers (small molecules) or polymers or includes a mixture of different organic materials or a mixture of different organic and inorganic materials. The at least one organic material is provided as a charge transport layer and thus does not have to be photoactive. A Schottky barrier is formed at the interface between the first electrode and the at least one organic material and/or between the second electrode and the at least one organic material. The Schottky barrier reduces leakage current in the off-state.

The Schottky barrier at the electrode/organic material junction is used as a naturally formed photodetector, where the detection mechanism is based on the internal photoemission process across the barrier. Photons incident on the at least one of the electrodes, e.g. the first electrode, also forming part of the Schottky barrier, are absorbed by the free electrons of the conductive electrode material. A part of the excited electrons reaches the Schottky interface and is emitted into the transport level of the at least one organic material if their energy is sufficiently high to surmount the Schottky barrier. These electrons contribute to the photocurrent. As the Schottky barrier is always lower than the energy gap of the at least one organic material, the mechanism allows detection of photons with energies lower than the energy gap (sub-gap photons).

The efficiency of the photoemission is significantly enhanced by the excitation of surface plasmons in a resonant manner at the electrode/organic material interface. According to the invention, at least one electrode, e. g. the first electrode, having a surface exposed to incident radiation, and where a Schottky barrier is formed between the at least one electrode and the at least one organic material, is structured so that it may comprise nano-apertures for exciting surface plasmon resonances, in particular sub-wavelength nano-apertures having nano-apertures within the layer of the electrode. The structure of the nano-apertures of the e.g. first electrode allows the incident light to couple resonantly to the electrode material's free electron gas and to generate surface plasmons. Surface plasmons are electromagnetic surface waves confined to a metal-semiconductor or metal-dielectric interface by coupling to the free electron plasma in metals. Incident radiation impinging on the e.g. first electrode with a wavelength which fits the surface plasmon resonance condition may couple with the nano-apertures and excite plasmons on the interface of the electrode with the at least one organic material. Surface plasmon resonances might include propagating surface plasmon polaritons and/or localized surface plasmon resonances.

Surface plasmons may decay into hot carriers with an energy that is sufficiently high to overcome the Schottky barrier, and may further be emitted into molecular states of the at least one organic material and contribute to the photocurrent. Surprisingly, electrical current is thus generated by the direct injection of plasmonically induced hot carriers from the electrode into the at least one organic material over a Schottky barrier. The observed extent of the effect is unexpected in organic photodetectors with regard to the prior art, as current scientific consensus is that, based on the large difference of electronic states and the energy level structure, the impact of energetically hot carriers is limited on organic devices.

A peak detection wavelength of an organic photodetector according to the invention, which corresponds to its design wavelength, is determined by the surface plasmon resonance condition and can be modulated by changing the structure of the nano-apertures, thereby achieving tunability in the responsivity of the organic photodetector according to the invention.

Wide bandgap organic semiconductors can be used as the at least one organic material because they do not absorb light in the region of interest. Preferably the at least one organic material has a wider band gap than the energy corresponding to the design wavelength, which provides a good Schottky barrier for low leakage current and exhibits compatibility with large-area deposition processes. This is in contrast to photovoltaic devices, where an absorption layer is generally required for generating an electrical power.

Organic photodetectors according to the invention feature several advantages. The responsivity and the shape of the spectral response of organic photodetectors according to the invention is controlled by the height of the Schottky barrier, which can be adjusted by methods such as selecting suitable materials obtained by “molecular engineering”, molecular doping, using different material combinations or applying a voltage over the barrier. The spectral response of the organic plasmonic Schottky photodetector with surface plasmon resonant enhancement can then be tuned and considerably enhanced by configuring the nano-apertures, for example designing the geometry and/or arrangement of the nano-apertures.

The plasmon resonance wavelength is selected by the configuration of the nano-apertures for enhancement of absorption by the Schottky barrier at a desired design wavelength corresponding to an energy below the optical gap of the at least one organic material. Therefore, the photodetector may selectively detect the incident radiation at a design wavelength of interest. For example, photodetectors which can detect radiation at a design wavelength in a desired infrared range may be used as infrared sensors. Furthermore, selection of organic materials is no longer limited by the design wavelength since the design wavelength can be tuned by the nano-apertures.

Advantageously, the organic photodetector according to the invention is wavelength selective, with maximum responsivity at the design wavelength.

Another advantage of organic photodetectors according to the invention is the following: Because photons incident on at least one of the electrodes, e.g. the first electrode, also forming the conductive, e.g. metallic, part of a Schottky barrier, are absorbed by the free electrons of the conductive material and thus do not need to travel through the organic material layer, their absorption related to fundamental molecular vibrations can be avoided.

The inventive organic photodetector is feasible in different embodiments depending on the respective case of application.

In one embodiment of the invention, the first electrode is deposited and structured on the substrate, the at least one organic material is deposited on the first electrode, and the second electrode is deposited on the at least one organic material so that the at least one organic material is interposed between to form a vertical configuration. The vertical configuration is a simple and less expensive sandwich structure.

In another embodiment of the invention, the at least one organic material is deposited on the substrate; the structured first electrode and the second electrode are provided on the at least one organic material so that the first electrode is spaced laterally apart from the second electrode to form a lateral configuration. Such a configuration does not require a transparent substrate and/or additional transparent or opaque layers on the substrate.

In a preferred embodiment of the invention a Fabry-Pérot cavity is formed by the at least one organic material between the first and the second electrode, wherein the Fabry-Pérot cavity requires the at least one organic material being transparent at least in the range of the design wavelength of the nano-apertures. Such a Fabry-Pérot cavity is suitable in the vertical or lateral configuration. The substrate, or one or both electrodes, or one or more additional mirror layers may act as a reflecting mirror. The one or more mirror layers might be designed as distributed Bragg reflectors (DBR). The thickness of the organic material layer defines the cavity thickness which is selected to provide cavity resonance at the design wavelength of the nano-apertures for the enhancement of light confinement. Advantageously, the Fabry-Pérot cavity can couple to the surface plasmon resonances of the organic photodetector according to the invention, which leads to a new optical mode. This coupled mode may contribute to the photocurrent and increase the current signal further.

The inventive photodetector may be realized on different substrates. They may be rigid or flexible. The substrate may be opaque or transparent depending on the conditions of application and/or on the configuration of the detector. For photodetectors having electrode/organic material/electrode structures, the so-called sandwich structures, the substrate mainly offers mechanical support.

The substrate can be further designed to form a transistor with an integrated photodetector. In this case, the substrate may comprise a dielectric layer and an electrode layer to form a third electrode which is provided as a gate electrode of an organic transistor. This transistor may be applied to vertical or lateral configurations.

The first and the second electrode are composed of highly conductive material such as metal, metal oxide, conductive polymer, graphene, carbon, carbon nanotube (CNT) or combinations thereof. They can be made from the same material or from different materials. The first and the second electrode may be fabricated by one of the well-known deposition methods like thermal evaporation, spin-coating, ink-jet printing, vapor-jet printing, nano-imprint, or roll-to-roll technique. The electrode may be used as a conductive electrode and a light sensitive layer for surface plasmon resonance at the same time.

The at least one structured electrode can be structured for instance by colloidal lithography which uses nanoparticles in the colloid as a mask on the electrode surface to fabricate nano-apertures. Alternatively, the at least one structured electrode may be structured by other lithography techniques, such as nano-imprint lithography, photolithography, orthogonal lithography, laser interference lithography, high resolution shadow masks, electron beam lithography, or any other.

In a further embodiment the nano-apertures are periodic, for example a periodic array of nano-apertures having a staggered or highly ordered arrangement. A periodic pattern is generally considered as a pattern with regularly recurrent structures wherein an actual pattern includes discontinuities and displacements within the long-range order. The periodic pattern can provide e.g. hexagonal or rectangular or other arrangements. Furthermore, the nano-apertures may be circular holes, triangular holes, rectangular holes or spaces between periodic arranged standing nano-figures, e.g. rods, etc.

Nano-apertures can improve transmission of the electrode when it is illuminated by incident radiation. Therefore, various electrically conductive materials including transparent, semi-transparent or non-transparent materials may be used as electrodes. Also non-regular structures may be used if they exhibit feature size in the wavelength range of interest. These could be fabricated by self-structuring techniques, e.g. using block copolymer template or metal annealing.

In another particularly preferred embodiment of the invention the organic photodetector is transparent in a wavelength spectrum which does not correspond to the spectrum of its design wavelength. Advantageously, this embodiment provides the opportunity of stacking the organic photodetector on top of other detectors, which feature a range of detection wavelengths in the spectrum the organic photodetector is transparent for.

The Schottky barrier height can be adjusted by inserting a thin oxide layer or a dopant layer between the first electrode and the organic material and/or between the second electrode and the organic material so that the Schottky barrier can be adjusted for the energy threshold of different wavelength range and to reduce leakage current.

The built-in potential between the electrode and the at least one organic material may be enhanced by using fully doped, contact doped or partially doped regions in the device in order to decrease the operation voltage.

The doping techniques may include molecular dopants, transition metal oxides, and salt complexes. The at least one organic material may be doped in n-type or p-type by using mixed dopant-matrix layers or pure dopant layers.

The photodetector can work in both directions, with a forward or a reverse bias. The magnitude of the bias can be used to increase or decrease its responsivity. Depending on the selection of organic materials, and/or the electrode materials the photodetector may be operated even without a bias.

### BRIEF DESCRIPTION OF THE DRAWINGS

Exemplary embodiments of the invention will now be described with reference to the drawings. In the drawings:

FIGS. 1a and 1b are schematic sectional views of a photodetector in a vertical configuration;

FIGS. 2a and 2b are schematic sectional views of a photodetector in a lateral configuration;

FIG. 3 is a schematic top view of an electrode with nano-holes;

FIG. 4 shows a SEM image of an electrode with nano-apertures;

FIG. 5 is a plot of curves of transmittance versus wavelength for the first electrode;

FIG. 6 is a plot of curves of absorptance versus wavelength with and without Fabry-Pérot cavity;

FIG. 7a is a plot of the measured absorptance spectrum of an organic semiconductor film;

FIG. 7b is a comparison of the responsivity spectra of a photodetector according to the invention and a reference device, and

FIG. 8 is a comparison of the responsivity spectra of organic photodetectors according to the invention with structured electrodes of different thickness.

### DETAILED DESCRIPTION OF THE DRAWINGS

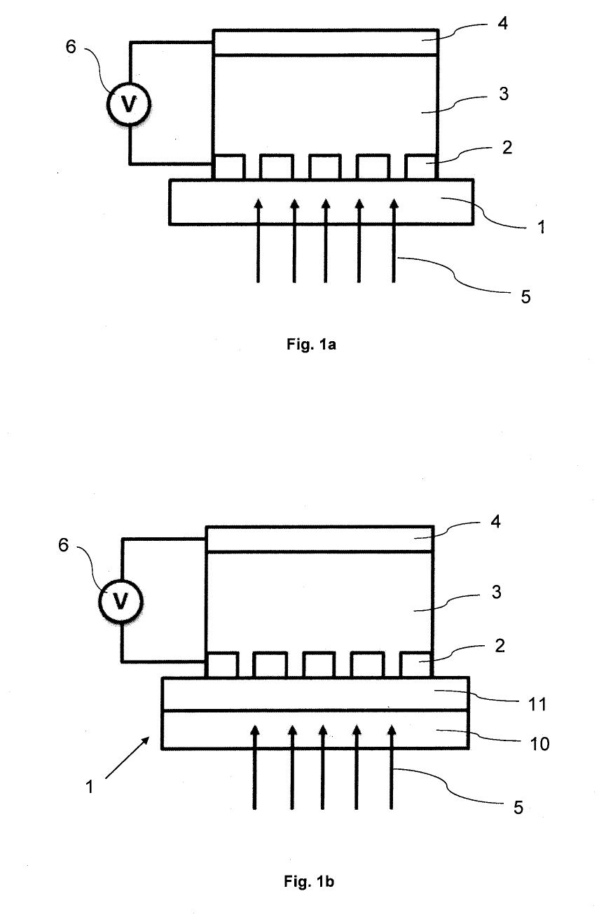

An exemplary photodetector in a vertical configuration is illustrated in FIG. 1a. The photodetector comprises a substrate 1, a first photoactive electrode 2, an organic material 3 as the charge transport layer and a second electrode 4 to form a sandwich structure. The organic material 3, for example small molecules or a polymer, has a wider band gap than the design wavelength of the photodetector, which provides a good Schottky barrier for low leakage current and exhibits compatibility with large-area deposition processes.

Substrate 1 is made of transparent materials such as glass or plastics for mechanical support. Under bottom illumination, incident light 5 may transmit through substrate 1 and impinge on the surface of first electrode 2.

First electrode 2 preferably comprises nano-apertures such as nano-apertures for exciting plasmon resonance on its surface faced to the organic material and is also used as a light absorbing and charge conducting electrode at the same time. A Fabry-Pérot cavity is formed between both electrodes 2, 4 by tuning the thickness of the organic material 3 to provide cavity resonance at a design wavelength of interest. The second electrode 4 may work as a mirror to reflect light for collecting photons more efficiently. The photodetector may be operated with a bias voltage 6 between two electrodes to enhance the responsivity thereof. This vertical configuration may provide an easy integration with further organic devices.

FIG. 1b shows another exemplary photodetector. Substrate 1 may comprise a transparent oxide layer 11 to form a gate dielectric of an organic transistor and an electrode layer 10 to form a gate electrode thereof. In this case, the organic transistor can work as photodetector.

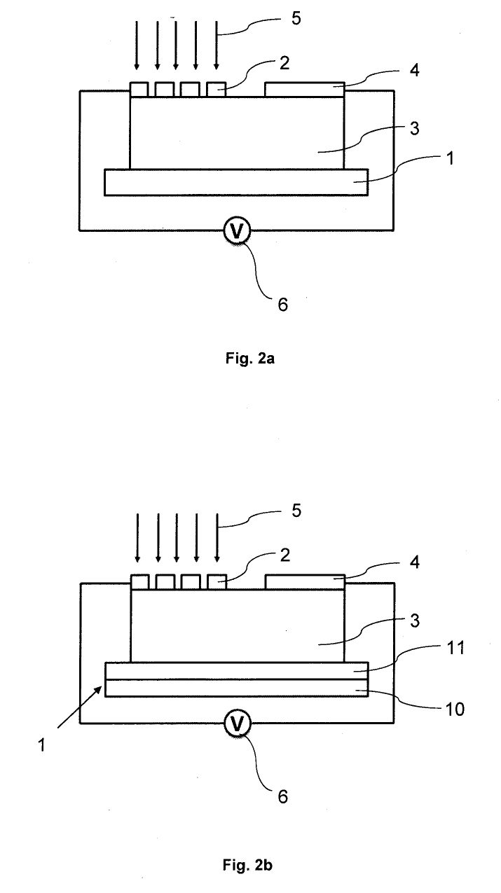

FIGS. 2a and 2b show further exemplary photodetectors in the lateral configuration which is a simple and versatile alternative to devices built in sandwich configuration. Both electrodes 2, 4 are arranged on top of the transparent organic material 3 spaced apart from each other. The substrate 1 serves as mechanical support (FIG. 2a) or as gate with a dielectric layer (FIG. 2b) as described above. Both embodiments may be operated with a bias voltage 6.

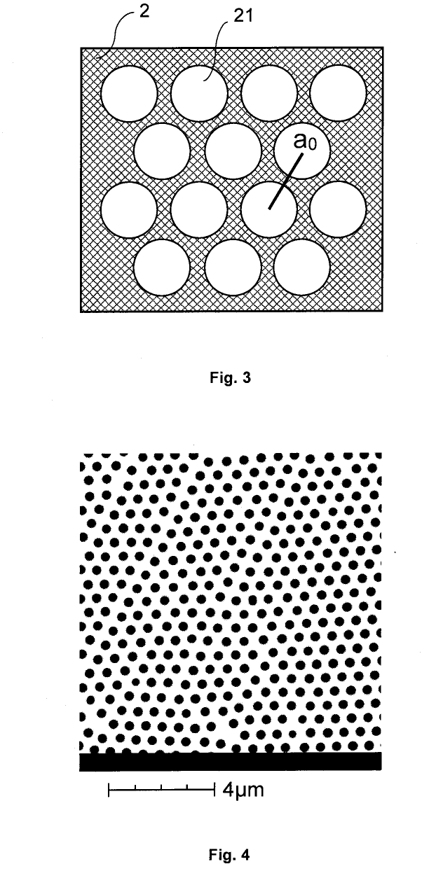

FIG. 3 shows an electrode, e.g. first electrode 2, having nano-apertures which are provided in form of hexagonally-ordered nano-holes 21 in metallic material 2. The wavelength of surface plasmon resonance λSPR can be determined by the following equation:

$${λ}_{SPR} = \frac{{a}_{0}}{\sqrt{{i}^{2} + {j}^{2} + ij}} \sqrt{\frac{3}{4} \frac{{ɛ}_{m} {ɛ}_{d}}{{ɛ}_{m} + {ɛ}_{d}}} ,$$

where a₀ is the distance between two holes, (i,j) the Bragg resonance orders, εₘ the dielectric function of the electrode and ε_{d} the dielectric function of the organic material. In this way, the design wavelength may be tailored by the nano-apertures.

FIG. 4 shows a SEM image of an electrode structured by colloidal lithography. For fabricating such nano-apertures, polymer particles such as polystyrene nanoparticles are packed into a hexagonal arrangement and placed onto a clean glass substrate. The nanoparticles are etched by oxygen plasma using RIE (reactive ion etching) to reduce the diameter of the nanoparticles, which also defines the size of the holes on the first electrode. In this manner, nano-apertures having sub-wavelength dimension can easily be produced. The nanoparticles serve as a lithographic mask. After the mask is formed with desired dimension and pattern, a thin metal layer is deposited on the mask, e.g. by thermal evaporation in vacuum, spin-coating, or various printing techniques etc. The nanoparticles are dissolved and removed by a lift-off process to form a continuous perforated metal electrode. FIG. 4 is an SEM image of the first electrode which is made of a 30 nm thick silver film. Nanoparticles were etched by oxygen plasma for 1 minute. The electrode has nano-apertures of an array of sub-wavelength holes with a hole-diameter of 337 nm and a period distance of 608 nm.

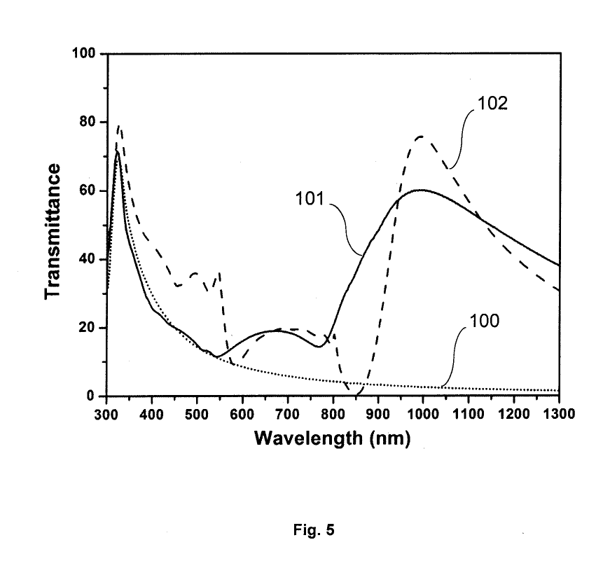

FIG. 5 shows experimental results of transmission of a silver film with and without nano-holes in comparison with simulation results. The simulation was carried out using parameters of an electrode shown in FIG. 4. Curve 100 is the transmittance of 30 nm thick silver film without nano-holes and can be regarded as a reference line. Light at a wavelength of about 350 nm can transmit through the closed silver film with a transmittance of about 70%. The transmittance drops dramatically as the wavelength increases. As shown by curve 101 which represents the measured transmittance of the electrode having nano-holes with hole diameters of 337 nm and a period of 608 nm. The silver film has another transmittance peak at a longer wavelength. The transmittance peak at a wavelength of about 1000 nm is caused by the surface plasmon resonance effect using nano-hole structures. Curve 102 represents simulation results, which show a good agreement with the experimental results. This indicates that the fabricated electrode has highly ordered nano-holes and is plasmonically active.

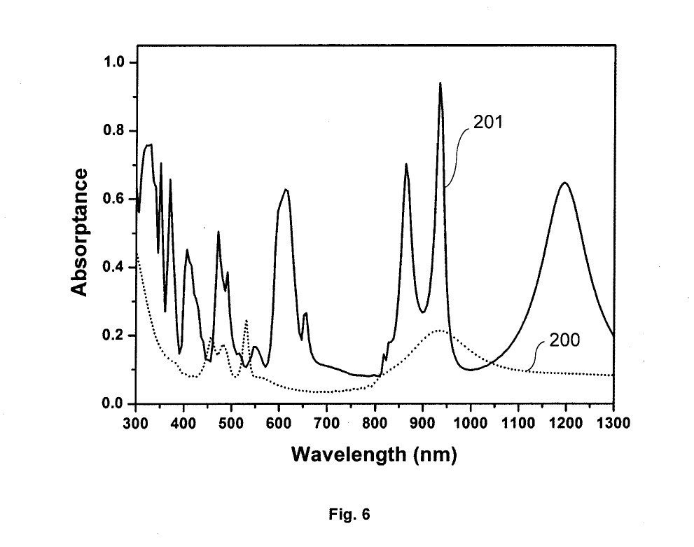

FIG. 6 shows the absorption enhanced by a Fabry-Pérot cavity, which is modeled by finite-difference time-domain simulations (FDTD). Curve 200 is the absorptance of a structured electrode made of a 30 nm thick silver film having nano-apertures as shown in FIG. 4, but without the second electrode as a mirror, i.e., without Fabry-Pérot cavity. Curve 200 can be regarded as a reference line. Curve 201 is the absorptance with a Fabry-Pérot cavity which is formed by a stack of 30 nm Ag/air/100 nm Al. With the help of the cavity, more efficient light collection is expected.

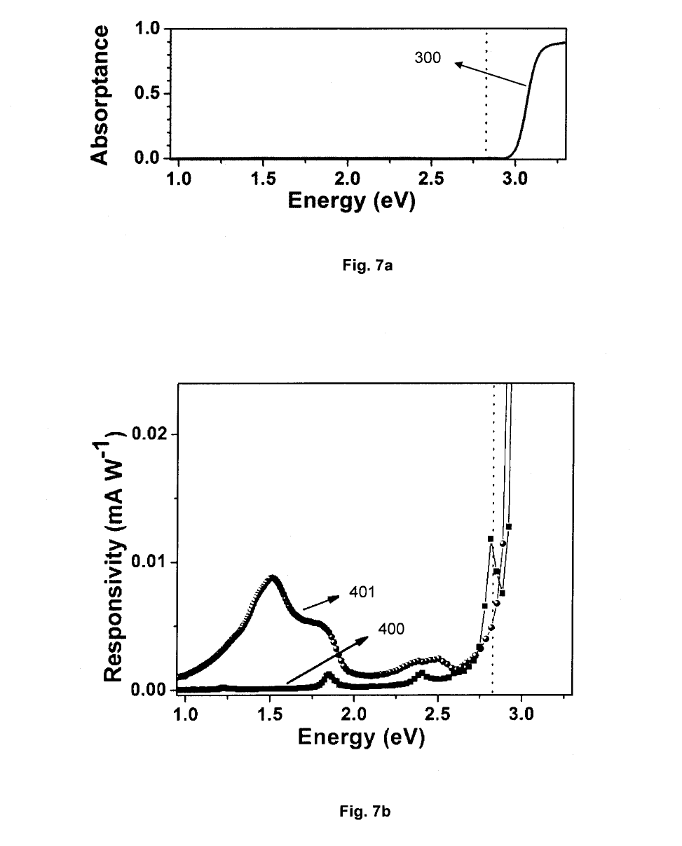

FIG. 7a shows the measured absorptance spectrum 300 of intrinsic 2,2′,7,7′-Tetrakis-(N,N′-di-p-methylphenylamino)-9,9′-spirobifluorene (spiro-TTB). It has a wide energy gap of approximately 3.4 eV and therefore shows only very weak absorption of photons in the visible region of the spectrum, which ranges approximately from 1.6 eV to 3.3 eV.

FIG. 7b show a comparison of the measured responsivity spectrum 401 of a photodetector according to the invention with a nano-hole structured electrode facing the incident radiation and the responsivity spectrum 400 of a reference device with a planar electrode facing the incident radiation. A tungsten-halogen lamp dispersed by a grating monochromator is used to illuminate the devices. When the lamp is turned on, the devices can be illuminated from the bottom side thereof with unpolarized, monochromatic light.

For the measurement of curve 401, a photodetector as described in FIG. 1 with bias voltage was fabricated using a spiro-linked compound as organic semiconductor. For the example, a 30 nm thick silver film was deposited on the substrate as the first electrode and structured using colloidal lithography to have nano-hole structures as shown in FIG. 4. A 500 nm thick 2,2′,7,7′-Tetrakis-(N,N′-di-p-methylphenylamino)-9,9′-spirobifluorene (spiro-TTB) layer was deposited on the first electrode and a 100 nm thick aluminum film on the organic semiconductor layer as the second electrode. The device used for measuring curve 400 features the same design with an unstructured silver film.

As displayed by curve 400, within the optical gap of spiro-TTB, the responsivity of the device with the planar silver film is low and increases with increasing photon energy, as expected for internal photoemission across the silver/spiro-TTB interface. The peaks located at photon energies of 1.29 eV, 1.92 eV, 2.46 eV and 2.88 eV correspond to resonant orders of the vertical Fabry-Pérot cavity formed by the device.

In contrast to curve 400, curve 401 shows a significantly improved responsivity, featuring a continuous band between 1 and 2 eV with a peak at approximately 1.5 eV, corresponding to a wavelength of approximately 830 nm. The detection mechanism can be summarized as follows: Photons are transmitted through the substrate and reach the interface between the electrode and the organic material. Around the surface plasmon resonance wavelength, photons couple with the nano-hole electrode and induce charge density oscillations, allowing a strong absorption in the electrode. The absorbed photons create surface plasmons, which decay non-radiatively into hot electrons. By applying an electric field between two electrodes, hot electrons can be injected into the organic materials and result in a detectable photocurrent.

The exemplary photodetector according to the invention demonstrates an enhanced sub-bandgap response in the near-infrared region. The contribution of the fundamental internal photoemission to the photocurrent still exists as a background signal, but is comparably small, and the spectrum is clearly dominated by the plasmon-induced signal. This photodetector has experimentally shown a detection peak at a wavelength of about 830 nm and may be used as an organic infrared sensor. The detection peak may be further tuned by changing the diameter and periodicity of nano-holes. The photocurrent may be increased by increasing the bias voltage, which results in improved responsivity.

Another advantageous feature of the organic photodetector according to the invention displayed in curve 401 is that the organic photodetector is optically inactive in the region of energies between 1.77 eV and 3 eV. By using a transparent spiro-TTB layer and the silver nano-hole structured electrode for plasmon excitation in the near-infrared region, a transparent window for higher energy photons can be opened up, which implies that the organic photodetector for the near-infrared spectrum can be stacked with a detector for the visible spectrum, by matter of example.

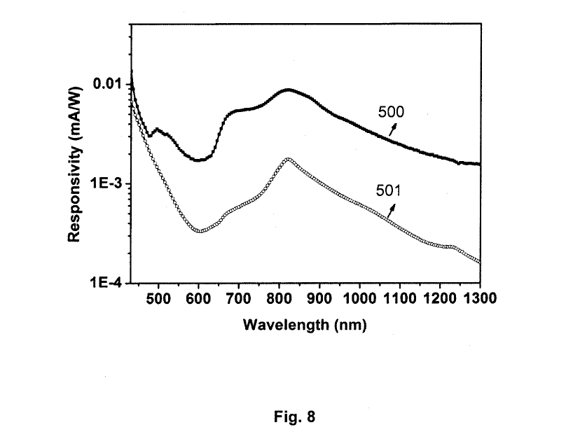

FIG. 8 shows a comparison of the responsivity spectrum 500 of an organic photodetector according to the invention as displayed in FIG. 1 with a nano-hole structured electrode of thin silver with a thickness of 30 nm, and the responsivity spectrum 501 of an organic photodetector according to the invention as displayed in FIG. 1 with a nano-hole structured electrode of thick silver with a thickness of 100 nm. Both curves 500, 501 display a pronounced peak in the responsivity around a wavelength of 830 nm. This demonstrates that optical transmission through the silver electrode is not essential for the working principle of the organic photodetector, as the organic semiconductor layer is not an active layer and does not need to absorb photons. The responsivity 500 of the thin electrode is still higher than that of the thick electrode because, to a certain extent, the thick silver layer impedes the progress of hot carriers to the Schottky junction.

### LIST OF REFERENCE NUMERALS

1 Substrate

2 First electrode

3 Organic material

4 Second electrode

5 Incident light

6 Bias voltage

10 Electrode layer

11 Dielectric layer

2 Metallic material

21 Nano-hole

100 Transmittance curve

101 Transmittance curve

102 Transmittance curve

200 Absorptance curve

201 Absorptance curve

300 Absorptance curve

400 Responsivity curve

401 Responsivity curve

500 Responsivity curve

501 Responsivity curve

1. An organic photodetector for detecting infrared, visible and ultraviolet radiation, comprising:
a substrate;
at least a first electrode and a second electrode wherein at least one electrode of the first electrode and the second electrode has a surface exposed to incident radiation;
a charge transport layer arranged between the first electrode and the second electrode, the charge transport layer comprising at least one organic material;
wherein a Schottky barrier is formed at an interface between the first electrode and the at least one organic material and/or at an interface between the second electrode and the at least one organic material;
wherein the at least one electrode having a surface exposed to incident radiation, and with a Schottky barrier formed between the at least one electrode and the at least one organic material, comprises nano-apertures for exciting surface plasmon resonances, wherein hot carriers generated by surface plasmon decay contribute to a photocurrent; and
wherein the nano-apertures are configured to selectively detect the incident radiation at a design wavelength.

2. The organic photodetector as claimed in claim 1, wherein the at least one organic material has a bandgap larger than an energy corresponding to the design wavelength.

3. The organic photodetector as claimed in claim 1, wherein the first electrode is formed on the substrate on which the at least one organic material is interposed between the first and the second electrode.

4. The organic photodetector as claimed in claim 1, wherein the at least one organic material is formed on the substrate, on which material the first and the second electrodes are disposed to be laterally spaced apart from each other.

5. The organic photodetector as claimed in claim 1, wherein a Fabry-Pérot cavity is formed between the first electrode and the second electrode and/or between the first electrode and the substrate by the at least one organic material being transparent at least in a range of the design wavelength of the nano-apertures, and a thickness of a charge transport layer comprising at least one organic material is selected to provide cavity resonance at the design wavelength.

6. The organic photodetector as claimed in claim 1, wherein the substrate comprises a dielectric layer and an electrode layer to form a third electrode which is provided as a gate electrode of an organic transistor.

7. The organic photodetector as claimed in claim 1, wherein the nano-apertures are provided in form of an array having a periodic arrangement.

8. The organic photodetector as claimed in claim 1, wherein the at least one electrode which comprises nano-apertures is transparent, semi-transparent or non-transparent to the incident radiation.

9. A method of producing an organic photodetector as claimed in claim 1, the method comprising:
providing a first electrode, a second electrode and at least one organic material on a substrate, where the at least one organic material is arranged between the first electrode and the second electrode; and
structuring at least one of the electrodes to form nano-apertures for exciting surface plasmon resonances;
wherein the at least one organic material is made of organic small molecules or a polymer to form a charge transport layer and to form a Schottky barrier between the first electrode and the at least one organic material and/or between the second electrode and the at least one organic material;
wherein the geometry and arrangement of the nano-apertures are adjusted to selectively detect incident radiation at a design wavelength for providing a tunable spectral response.

10. The method of producing an organic photodetector as claimed in claim 9, wherein the at least one organic material is chosen to have a bandgap larger than an energy corresponding to the design wavelength of the organic photodetector.

11. The method of producing an organic photodetector as claimed in claim 9, wherein the first electrode is deposited on the substrate, the at least one organic material is deposited on the first electrode, and the second electrode is deposited on the at least one organic material to form a vertical configuration.

12. The method of producing an organic photodetector as claimed in claim 9, wherein the at least one organic material is deposited on the substrate, the first and the second electrode are provided on the at least one organic material, wherein the first electrode is spaced laterally apart from the second electrode to form a lateral configuration.

13. The method of producing an organic photodetector as claimed in claim 9, wherein the at least one organic material is transparent at least in a range of the design wavelength of the nano-apertures, and a thickness of the at least one organic material is selected to form a Fabry-Pérot cavity between the first and the second electrode and/or between the first electrode and the substrate for providing cavity resonance at the design wavelength.

14. The method of producing an organic photodetector as claimed in claim 9, wherein at least one of the electrodes is structured to form an array of nano-apertures having a periodic arrangement.

15. The method of producing an organic photodetector as claimed in claims 9, wherein an oxide layer and/or a dopant layer is deposited between the first electrode and the at least one organic material and/or between the second electrode and the at least one organic material to adjust the Schottky barrier.
